(19) United States
(12) Patent Application Publication
(10) Pub. No.: US 2021/0341834 A1
(43) Pub. Date: Nov. 4, 2021

(54) METHOD OF MANUFACTURING A STAMP FOR IMPRINT LITHOGRAPHY, STAMP FOR IMPRINT LITHOGRAPHY, IMPRINT ROLLER AND ROLL-TO-ROLL SUBSTRATE PROCESSING APPARATUS

(71) Applicants: Jens DEGENHARDT, Jüchen (DE); John MALTABES, Alzenau (DE); Applied Materials, Inc., Santa Clara, CA (US)

(72) Inventors: Jens DEGENHARDT, Jüchen (DE); John MALTABES, Alzenau (DE)

(21) Appl. No.: 17/274,026

(22) PCT Filed: Sep. 12, 2018
(86) PCT No.: PCT/EP2018/074622

§ 371 Date: Mar. 5, 2021

(51) Int. Cl. G03F 7/00; B29C 59/04; B29C 35/08

(52) U.S. Cl. CPC G03F 7/0015; G03F 7/0002; B29L 2031/756; B29C 35/0805; B29C 2035/0827; B29C 59/046

(57) ABSTRACT

A method of manufacturing a stamp for imprint lithography is described. The method includes coating a master with a layer system, comprising a first layer and a second layer, the second layer being on top of the first layer, the master providing a template of an imprint structure. The method further includes providing a stabilization element over the second layer, the stabilization element having a higher bending resistance than the second layer, and separating the master from the layer system to expose the imprint structure.

### TECHNICAL FIELD

Embodiments of the disclosure relate to imprint lithography. In particular, embodiments of the disclosure relate to methods of manufacturing a stamp for lithography. Further, embodiments of the disclosure relate to an imprint roller including a stamp for imprint lithography and substrate processing apparatuses including an imprint roller.

### BACKGROUND

Patterning of thin films is used for a plurality of applications, for example manufacturing of microelectronic devices, optoelectronic devices, or optical devices. Optical lithography techniques may be used for patterning thin films in a device. However, optical lithography techniques may be expensive and may reach the limits for example on substrates having larger sizes and/or on flexible substrates.

Particularly for roll-to-roll processing, there is a limitation in manufacturing of small feature sizes using conventional techniques without the use of expensive photolithography. Printing techniques such as screen print, gravure, flexographic, inkjet, etc., are for example limited to feature sizes, e.g. >10 μm, which may not be sufficiently small. In addition, sheet-to-sheet processes can benefit from imprint lithography processes. Imprint lithography may provide for a comparably inexpensive process for patterning a thin film in order to provide a patterned structure in a device. Furthermore, imprint lithography is comparably fast, which can save equipment and operator time.

There are several technical challenges with respect to manufacturing imprint lithography stamps and imprint rollers for roll-to-toll apparatuses. For example, typically the stamp can be made of a soft material, e.g. a soft polymeric material, which can pose some problems with respect to maintaining dimensional stability of the stamp. For instance, for manufacturing of structures for displays, maintaining dimensional stability is critical to ensure that the structures line up with the pixels. Further, for producing imprint rollers with an imprint stamp on the roller surface for Roll-to-Roll (R2R) manufacturing, the transfer of the imprint stamp to the roller surface is challenging, particularly with respect to ensuring dimensional stability during the transfer process.

Hence, in view of the above, there is a continuous demand for improved methods of manufacturing a stamp for imprint lithography, stamps and imprint rollers as well as for roll-to-roll imprint apparatuses employed for imprint lithography.

### SUMMARY

In light of the above, a method of manufacturing a stamp for imprint lithography, a stamp for imprint lithography, and an imprint roller for a roll-to-roll substrate processing apparatus are provided.

According to an aspect of the present disclosure, a method for manufacturing a stamp for imprint lithography is provided. The method includes coating a master with a layer system comprising a first layer and a second layer, the second layer being on top of the first layer, the master provides a template of an imprint structure. The method further includes providing a stabilization element over the second layer, wherein the stabilization element having a higher bending resistance than the second layer. The method further includes separating the master from the system to expose the imprint structure.

According to another aspect of the present disclosure, a stamp for imprint lithography is provided. The stamp includes a stamp support structure, an imprint structure having a plurality of features generating a pattern upon imprinting the stamp in a layer, wherein the imprint structure is provided by a layer system comprising a first layer and a second layer, the second layer being on top of the first layer. The stamp further includes a stabilization element over the second layer, the stabilization element being attached being attached to the stamp support structure, particularly by an adhesion layer, the stabilization element having a higher bending resistance than the second layer.

According to a further aspect of the present disclosure, an imprint roller for a roll-to-roll substrate processing apparatus is provided. The imprint roller includes a stamp according to any embodiments described therein, wherein the stamp support structure is a cylindrical support structure.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIGS. 1 to 9 show schematic illustrations of exemplary method steps of a method of manufacturing a stamp for imprint lithography according to various embodiments described herein;

FIG. 10 shows a schematic view of an exemplary attaching process, wherein the stamp is attached to a stamp support structure;

FIG. 11 shows an imprint roller for a roll-to-roll substrate processing apparatus according to the present disclosure;

FIG. 12 shows a flowchart for illustrating a method of manufacturing a stamp for imprint lithography according to embodiments described herein; and

FIG. 13 shows a schematic view of a roll-to-roll substrate processing apparatus according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

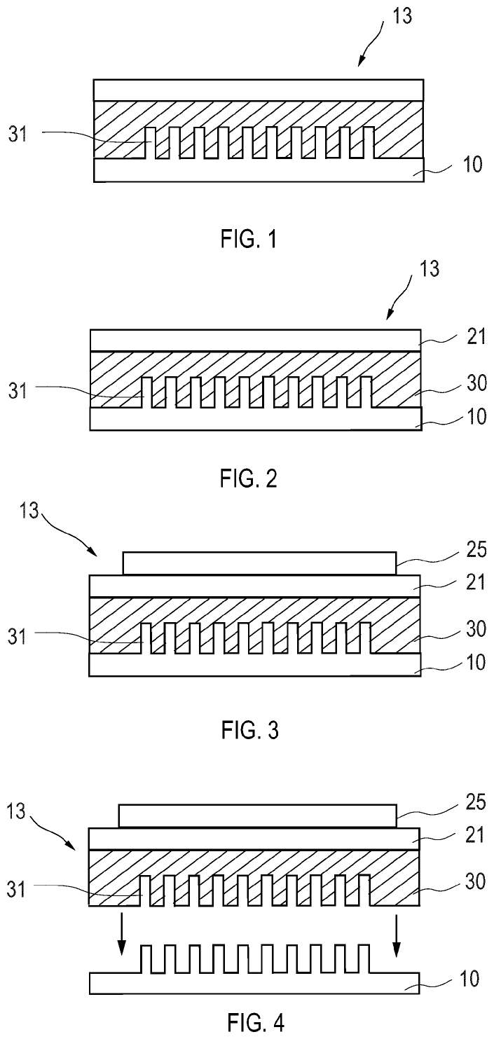

With exemplary reference to FIGS. 1 to 8, embodiments of a method for manufacturing a stamp for imprint lithography according to the present disclosure are described. According to embodiments which can be combined with any other embodiments described herein, the method includes coating a master 10 with a layer system 30 (see FIG. 1) wherein the master 10 provides a template of an imprint structure 31. The layer system 13 includes a first layer 30 and a second layer 21 on top of the first layer 30 (see FIG. 2) and providing a stabilization element 25 over the second layer 21. The stabilization element 25 has a higher bending resistance than the second layer 21 (see FIG. 3). The method further includes separating the master 10 from the first layer 30 to expose the imprint structure 31 (see FIG. 4). Typically, the imprint structure 31 is provided by coating a master 10 having a negative template 32 of the imprint structure 31 as exemplary shown in FIG. 7.

Accordingly, as exemplary shown in FIG. 1, coating a master 10 with a layer system 13 can include applying a coating or a layer system on a surface of the master wherein various coating processes can be used. The coating can be, for example, applied by chemical, mechanical, thermal and/or thermomechanical processes like CVD, PVD, PECVD, vapor deposition, spin coating and/or spin casting. The coating of the master 10 with the layer system 13 provides a layer system 13 with a template of an imprint structure 31 based on a pattern of the master 10, in particular a pattern of the surface of the master as described therein.

Accordingly, as exemplary shown in FIG. 2, the layer system 13 further includes a second layer 21 on top of the first layer 30. The layer system 13 can also be understood as a layer stack 13 including the first layer and the second layer. The layer system 13 can for example be a material provided by SCIL Nanoimprint Solution. The second layer 21 can beneficially protect the first layer 30 during stamp manufacturing against direct contact and/or against impurities. In particular, the second layer can also act as an adhesion layer. According to embodiments, which can be combined with other embodiments described herein, the layer system can also be formed by providing a layer over a further layer wherein the layer corresponds to the second layer and the further layer corresponds to the first layer of the layer system. Furthermore, according to embodiments which can be combined with other embodiments described herein, the second layer can also be formed by a chemical or physicochemical surface modification out of the first layer.

Accordingly, with reference to FIG. 3, providing a stabilization element 25 over the second layer 21 can, for example, be understood as putting, laying, superimposing, locating, adding or the like a stabilization element 25 on top of the second layer 21. The provided stabilization element 25 can be in direct contact with the second layer 21, in particular with the upper surface of the second layer 21. The second layer 21 can be configured to form a plane or a flat upper surface, wherein the stabilization element 25 is put on top of the upper surface of the second layer 21. A bottom or an underside of the stabilization element 25 can connect the second layer 21, wherein connecting can also be described in that the bottom of the stabilization element 25 is put in direct contact with an upper surface of the second layer 21. Putting the stabilization element, in particular the bottom side of the stabilization element 25, in direct contact with the upper surface of the second layer 25 can also be understood as the stabilization element 25 clings or fits closely on top of the second layer 21. The stabilization element 25 and the second layer can also stick together or adhere to one another due to adhesion forces when bringing the respective surfaces of the stabilization element 25 and the second layer 21 in contact with each other.

According to some embodiments, which can be combined with other embodiments described herein, the stabilization element 25 can have flat-shaped body forming an even bottom surface and an even upper surface, wherein the bottom surface and the upper surface of the stabilization element 25 can be essentially parallel to each other. According to embodiments, which can be combined with other embodiments described herein, the upper surface of the second layer 21 is essentially parallel to the upper surface and/or the bottom surface of the stabilization element 25. Providing the stabilization element 25 with a bottom surface being essentially parallel to the upper surface of the second layer can improve the stability of the stamp, in particular when handling the stamp during further processing.

In the present disclosure, the feature “the stabilization element having a higher bending resistance than the second layer”, can be understood in that the stabilization element includes a material and/or components with a higher rigidity than the material and/or components of the second layer. The stabilization element having a higher bending resistance than the second layer can also be described as the stabilization element having a higher rigidity than the second layer. Rigidity can be understood as, for example, torsional rigidity, flexural rigidity, shear rigidity and/or tensile rigidity.

Accordingly, with reference to FIG. 4, the method further includes separating the master 10 from the first layer 30 to expose the imprint structure 31. Separating the master 10 from the first layer 30 can include a cutting process, wherein the master 10 is cut off from the first layer 30. In particular, the master 10 is cut off from the first layer 30 at least in the “edge areas” located adjacent to the imprint structure 31 of the first layer 30, wherein the cutting process can be carried out, for example, by a blade, by a laser or the like. Separating the master can include pulling off the master 10 from the first layer 30. Separating the master can also include a separation by an air knife or blade using a laminar airflow, in particular a streamline flow.

Advantageously, the stabilization element can stabilize the first layer and the second layer when separating the master from the first layer by providing resistance against deformation of the first and second layer. In particular, the stabilization element can be supported or held during separating to provide a back pressure or a counter force against the separation force applied between the master and first layer. The stabilization element can counteract a deformation of the layer stack including the first layer and the second layer, in particular of the imprint structure of the first layer. Furthermore, the stabilization element can work against distortion due to the rigidity of the stabilization element of the imprint structure to protect the pattern of the imprint structure. Moreover, the stabilization element can improve the handling, in particular the safe handling of the stamp after separating the master from the first layer. The stabilization element can also provide a contact surface for further transporting during the manufacturing process to facilitate the transport of the stamp.

Accordingly, embodiments of the method of manufacturing a stamp for imprint lithography as described herein can be improved compared to conventional manufacturing methods. More specifically, by embodiments of the method for manufacturing a stamp lithography as described herein, the template having the imprint structure is stabilized throughout the manufacturing process, wherein the structure and the dimensional stability of the imprint structure can be ensured during the stamp production. Moreover, the dimensional stability of the first layer and the second layer can be enforced.

Before various further embodiments of the present disclosure are described in more detail, some aspects with respect to some terms used herein are explained.

In the present disclosure, a “stamp for imprint lithography” can be understood as a stamp which is configured for being utilized in an imprint lithography process. In the present disclosure, the “first layer” can be made of a polymer material, particularly a curable polymer material. For instance, the first layer can be made of an elastomer, e. g. a silicon elastomer. According to an example, the first layer may be made of xPDMS.

In the present disclosure, the “second layer” can be made of a polymer material, particularly a curable polymer material. A curable polymer material as described herein can be understood as a polymer which can be cured through the application of heat and/or radiation. In other words, a curable polymer material can be understood as a polymer material which can be toughened or hardened by polymerization with or without cross-linking of polymer chains, e. g. induced by heat, radiation or chemical additives.

In the present disclosure, a “template having an imprint structure” can be understood as a three-dimensional structure having a pattern to be imprinted. Typically, the three-dimensional structure is a negative structure of the structure to be imprinted. For instance, the imprint structure of the template can include a plurality of features. Typically, the plurality of features include side surfaces, bottom surfaces and top surfaces. For example, a multi-level imprint structure may further include various bottom surfaces at different levels.

According to some embodiments, which can be combined with other embodiments described herein, the plurality of features of the imprint structure can have the same feature width and the same feature of depth. Additionally or alternatively, different features of the imprint structure may have different feature geometries, i. e. different feature widths and different feature depths. Yet further, two or more features with different sizes may be placed next to each other in a repeating manner to form a repeating pattern. For example, the pattern features can be selected from the group consisting of: a line, a pole, a trench, a hole, a circle, a square, a rectangle, a triangle, other polygons, a pyramid, plateaus, and combinations or arrays thereof.

According to some embodiments which can be combined with other embodiments described herein, the method further includes curing the first layer. In particular, curing the first layer may include exposing the first layer to heat and/or radiation. For example, curing the first layer may include exposing the first layer to a curing temperature T_{c} of 65° C.≤T_{c}≤105° C., particularly a curing temperature of 75° C.≤T_{c}≤95° C., more particularly a curing temperature of 80° C.≤T_{c}≤90° C., e.g. a curing temperature of approximately 85° C. Further, curing the first layer may include exposing the first layer to a curing temperature T_{c} as described herein for a curing time t_{c} of 2 h≤t_{c}≤6 h, particularly a curing time of 3 h≤t_{c}≤5 h, more particularly 3.5 h≤T_{c}≤4.5 h, e. g. a curing time t_{c} has a curing time of approximately 4 h.

According to embodiments, which can be combined with other embodiments described herein, the stabilization element is attached to the second layer. Attaching can be understood as the adhesion between the stabilization element and the second layer, in particular between the lower bottom surface of the stabilization element and the upper surface of the second layer, as described herein, is reinforced or enhanced. The attaching can include, for example, adding an adhesive on the respective surfaces of the stabilization element and/or the second layer wherein the adhesive forms a connection between the stabilization element and the second layer. The adhesive can be selected from the group consisting of: glue, paste, adhesive layer, lacquer, adhesive lacquer or the like. The adhesion between the stabilization element 25 and the second layer 21 can be also promoted by chemical modification or plasma treatment. The stabilization element 25 can also be glued to the underlying second layer. Attaching the stabilization element can be also include applying a mechanical force, wherein the stabilization element is pressed on the second layer.

Furthermore, attachment of the stabilization element to the second layer can be enhanced by plasma activation, in particular by surface modification of the stabilization element by plasma activation. By attaching the stabilization element to the second layer, the stability of the entire stamp, in particular the dimensional stability between the first layer, the second layer and the stabilization element can be reinforced. In particular, the bending resistance of the stabilization element can enhance the protection against deformation of the second and the first layer by attaching the stabilization element on the second layer on as described herein.

According to embodiments, which can be combined with other embodiments described herein, providing a stabilization element over the second layer 21 further includes providing an intermediate layer, particularly attaching the intermediate layer 24 to the second layer 21, as exemplary shown in FIG. 5 The intermediate layer 24 can be understood as a support layer or an auxiliary layer. The intermediate layer can be for example heat cured by exposing the intermediate layer to a curing temperature between 65° C. and 75° C. for a curing time of about 4 to 6 min. The intermediate layer can also be subsequently subjected to a post cure process for about 2 to 48 hours. The intermediate layer 24 can be configured to provide an adhesive promotion between the first layer and the second layer to facilitate the attachment of the second layer 21 on top of the first layer 30. Moreover, the intermediate layer can be configured to protect the first layer, in particular the imprint structure of the first layer, during further processing of the stamp. According to embodiments, which can be combined with other embodiments described herein, the layer stack 13 can also include the intermediate layer 24 located between the first layer 30 and the second layer 21. Furthermore, the intermediate layer 24 can also be understood as a sublayer of the second layer 21.

According to some embodiments, which can be combined with other embodiments described herein, curing the first layer includes irradiating the first layer through the stabilization element. Curing the first layer by irradiating the first layer through the stabilization element can enable a uniform and steady curing, wherein the curing temperature applied to the first layer is at least partly generated by absorption of the radiation within the first layer. Moreover, the curing of the first layer by irradiating the first layer though the stabilization element can enable curing the first layer after providing the second layer and the stabilization element during the manufacturing process, wherein the manufacturing process can be shortened.

According to some embodiments, which can be combined with other embodiments described herein, curing the second layer includes irradiating the second layer through the stabilization element. FIG. 6 shows a schematic example of the curing process. The upper surface 25a of the stabilization element 25 is irradiated by an irradiation source (not shown), wherein the radiation 63 enter the upper surface 25a of the stabilization element 25 and penetrate the stabilization element 25. The irradiation 63 enters the second layer 21 through the stabilization element 25 and the radiation 63 is at least partly absorbed within the second layer 21, wherein heat for curing the second layer 21 is generated. At least a part of the radiation 63 can further penetrate the second layer 21 and enter the first layer 30 arranged below the second layer 21. Likewise, heat is generated in the first layer 30 by absorbing the radiation 63 within the first layer 30, to enable and/or support the curing of the first layer 30.

According to some embodiments, which can be combined with other embodiments described herein, the heat generated by absorbing the radiation can support or enable curing the first layer 30 and/or the second layer 21. Furthermore, absorbing the radiation can cure the pattern of the imprint structure 31 adjacent to the master 10 to improve forming the imprint structure 31. Moreover, the radiation 63 through the stabilization element 25 can support the adhesion within a first boundary area 23 located between the second layer 21 and the stabilization element 25 to improve the attachment of the stabilization layer 25 to the second layer 21, for example, by hardening and/or curing an adhesive as described herein. Likewise, the radiation 63 through the stabilization element 25 can support the adhesion in a second boundary area 24 located between the second layer 21 and the first layer 30. According to some embodiments, which can be combined with other embodiments described herein the intermediate layer arranged between the second layer and the first layer can be cured by irradiating the first layer through the stabilization element.

According to embodiments, which can be combined with other embodiments described herein, the method further includes supporting the layer system, in particular the first layer by a support surface, wherein the support surface is in contact with the imprint structure of the first layer. The support surface can be, for example a plate, with an even surface wherein the stamp can be put on after separating the master from the first layer. The plate can be for example a glass plate, a plastic plate, a ceramic plate or the like. Supporting the first layer by the support surface protects the imprint structure by covering the surface of the imprint structure after releasing the imprint structure from the master.

Furthermore, providing the support surface can facilitate further processing steps like arranging the stamp to a stamp support structure or the like. Moreover, the support surface can be transparent to light, in particular transparent to light waves in the visible range to enable monitoring of the pattern of the imprint structure through the support surface. By monitoring the imprint structure through the support surface, the imprint structure can be measured to detect errors in the imprint structure. Furthermore, by monitoring the imprint structure through the support surface, the first layer can be aligned on the support surface to improve the line up from the imprint structure when attaching the stamp for example in a further step to a stamp support structure.

According to embodiments, which can be combined with other embodiments described herein, the method further includes providing an adhesion layer on exposed edge portions of the stabilization element, the second layer and the first layer. Providing an adhesion layer can also be understood as embedding the exposed edge portions, in particular the external surfaces of the edges portions of the first, of the second and of the stabilization element with an additional adhesion layer. FIG. 8 shows a schematic view of an exemplary stamp manufactured according to embodiments described herein, wherein an adhesion layer is provided.

The adhesion layer 42 surrounds the outer surfaces of first layer 30, of the intermediate layer 24, of the second layer 21, and of the stabilization element 25. The imprint structure 31 in the first layer 30 is covered by a support surface 15 wherein the imprint structure 31 is protected for being in contact with the adhesion layer 42. The material of the adhesion layer 42 can also enter or flow into the edge portion between the respective layers 21c, 24c and 30c to provide additional dimensional stability between the respective layers of the stamp. Furthermore, the adhesive layer 42 can be configured to form adhesive surfaces, wherein further handling or arranging the stamp to a further support structure can be facilitated. According to some embodiments, which can be combined with other embodiments, the adhesion layer is permeable to radiation, in particular permeable to UV-radiation.

FIG. 9 shows a schematic top view of FIG. 8 including a stamp with a first layer 30 having two imprint structures 31a and 31b. The imprint structures 31a and 31b of the first layer (not shown) are covered by the adhesion layer 42, the stabilization element 25, the second layer (not shown) and the intermediate layer (not shown) as described in FIG. 8.

According to embodiments which can be combined with other embodiments described herein, the adhesion layer 42 has a width between 300 μm-1000 μm. According to embodiments, which can be combined with other embodiments described herein, the stabilization element 25 has a width between 200 μm and 500 μm. According to embodiments, which can be combined with other embodiments described herein, the intermediate layer 24 has a width between 30 μm and 100 μm. According to embodiments, which can be combined with other embodiments described herein, the second layer 21 has a width between 30 μm and 100 μm. According to embodiments, which can be combined with other embodiments described the first layer 30 has a width between 30 μm and 100 μm.

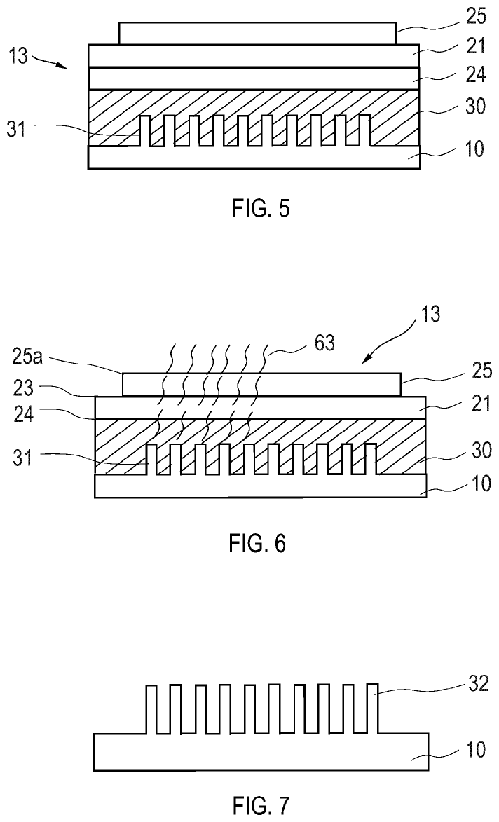

According to embodiments, which can be combined with other embodiments described herein, the method further includes attaching the stabilization element to a stamp support structure, particularly wherein attaching the stabilization element comprises rolling the stamp support structure over the stabilization element. With reference to FIG. 10 showing a schematic view of an exemplary attaching process, wherein the stamp 12 is attached to a stamp support structure 40. The stamp support structure 40 is rolled over the stabilization element 25 in a rolling direction 52, wherein the stamp support structure 40 makes contact with the surface of adhesive layer 42. By the movement of the stamp support structure 40 over stamp 12 the stamp support structure 40 exerts a pressure on top of the adhesive layer 42, wherein the adhesive layer 42 becomes attached to the surface of the stamp support structure 40. According to embodiments, the surface of the support structure 40 can be provided with an adhesive 46, a glue or the like in order to attach or to improve the attachment of the adhesive layer 42 to the surface of the stamp support structure 40.

According to embodiments, which can be combined with other embodiments described herein, attaching the stabilization element to the stamp support structure comprises rolling the stamp support structure over the stabilization element, wherein rolling the stamp support structure over the stabilization element comprises separating the master from the first layer to expose the imprint structure.

According to embodiments, which can be combined with other embodiments, a stamp for imprint lithography is provided. The stamp includes a stamp support structure, an imprint structure having a plurality of features generating a pattern upon imprinting the stamp in a layer, wherein the imprint structure is provided by a layer system including a first layer and a second layer, the second layer being on top of the first layer, and the stamp further includes a stabilization element over the second layer, wherein the stabilization element is attached to the stamp support structure, particularly by an adhesion layer, wherein the stabilization element has a higher bending resistance than the second layer. The stamp can be manufactured by embodiments described herein.

According to embodiments, which can be combined with other embodiments described herein, the stabilization element is permeable to radiation, in particular permeable to ultraviolet radiation. The stabilization element can include materials and/or consist of materials which are permeable to radiation. The stabilization element can, for example, be made of glass, in particular quartz glass, willow glass, metallic glass, amorphous metal or the like. Furthermore, the stabilization element can be made of materials like polymers, in particular cyclo-olefin polymers (COP), and/or varnish, in particular photo lack. Using the aforementioned materials for forming the stabilization element can provide several advantageous aspects. For example, the stabilization element can provide a sufficient rigidity to stabilize the different layers in the stamp as well as provide a sufficient flexibility when being attached to the stamp support structure, in particular to a curved stamp support structure. Additionally, the aforementioned materials have a high in-plane stiffness, which enable a separation of the master from the first layer without distorting or warping the imprint structure within the first layer.

Furthermore, the aforementioned materials provide sufficient permeability of light, in particular of UV-light wherein a curing of the layers located below the stabilization element, in particular the first layer and the second layer, can be enabled by irradiation through the stabilization layer as described herein. Moreover, a stabilization layer being permeable to light enables to radiate through the stabilization layer during an imprinting process with the stamp according to embodiments described herein, wherein the imprinting process of the material can be improved.

According to some embodiments, which can be combined with other embodiments described herein, the stabilization layer can have the shape of a foil or of a thin layer. Furthermore, the stabilization element can also be lattice-shaped wherein the stabilization layer has rigid structure with recesses or cut-out which are filled with a light permeable material as described above.

According to some embodiments, which can be combined with other embodiments described herein, the layer system 13 further includes an intermediate layer 24 being arranged between the first layer 30 and the second layer 21, as exemplary shown in FIG. 5. The intermediate layer can provide an adhesion promotion between the first layer and the second layer as described herein.

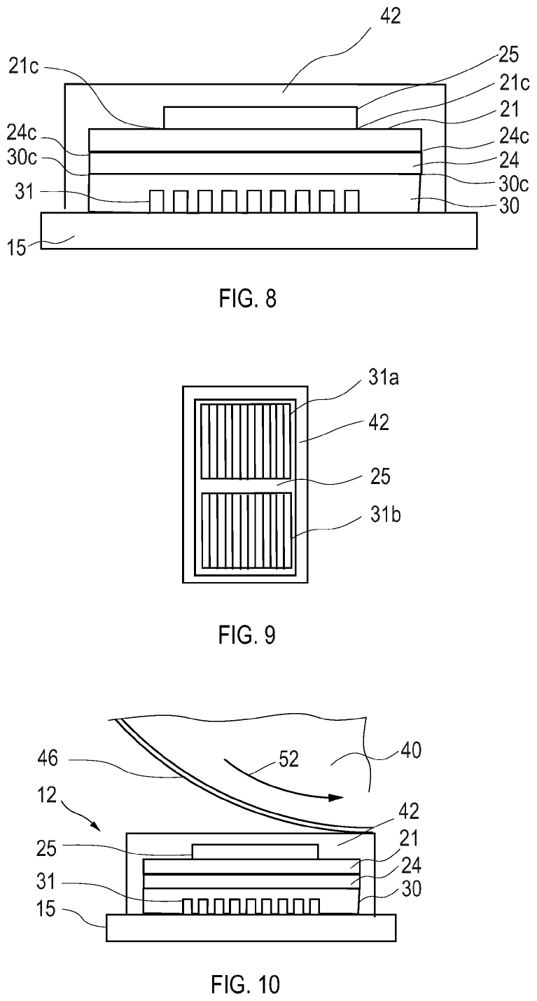

With reference to FIG. 11 an imprint roller 200 for a roll-to-roll substrate processing apparatus according to the present disclosure is described. According to embodiments which can be combined with other embodiments described herein, the imprint roller 200 includes a stamp 12 having an imprint structure 31. The stamp 12 is attached to the surface of the cylindrical support structure 40 by an adhesion layer 42. The adhesion layer 42 surrounds the outer surfaces of the first layer 30, the intermediate layer 24, the second layer 21, and the stabilization element 25 according to embodiments described herein. The first layer 30 includes an imprint structure 31 as described herein. According to some embodiments which can be combined with other embodiments, the stamp support structure and/or the stabilization element has a bending radius in the range of 5 cm to 10 cm, or more particularly in the range of 7 cm to 8 cm.

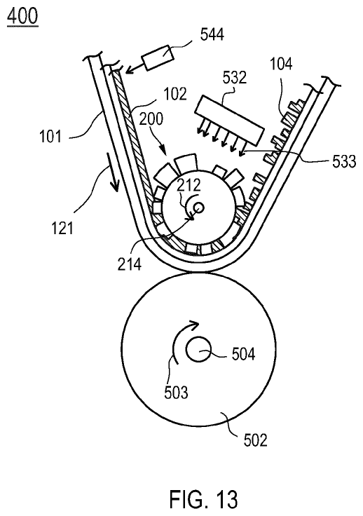

With exemplary reference to FIG. 13, a roll-to-roll substrate processing apparatus 400 according to the present disclosure is described. As exemplary shown in FIG. 13 the roll-to-roll substrate processing apparatus 400 includes an imprint roller 200 according to embodiments described herein. For imprint lithography in an R2R process, the imprint roller 200 may rotate around the rotation axis 214 and the substrate 101 is moved over the surface of a rotor, for example a cylindrical surface of another roller, e. g. the roller 502 shown in FIG. 13. For example, the substrate transport velocity v can correspond to the angular velocity w of the roller 502 according to the formula v=r*w, wherein R is the radius of the roller. That is, the substrate transport velocity is similar to the cross-radial velocity, i.e. the tangential velocity, of the roller.

As exemplary shown in FIG. 13, the roll-to-roll substrate processing apparatus 400 typically includes an imprint station including an imprint roller 200 which can rotate around axis 214 of the imprint roller 200. FIG. 13 illustrates the rotation by arrow 212. Upon rotation of imprint roller 200, a pattern of a stamp attached to the roller or being a portion of the roller is imprinted in a layer 102 to be imprinted, e.g. a layer of conductive paste, a lacquer, a photoresist or the like. For illustration purposes the imprint structure 31 is shown in an enlarged manner in FIG. 13.

Accordingly it is to be understood that the apparatus as described herein can be configured for performing an imprint lithography process with a conductive paste. For instance, the conductive paste can form the basis for a functional layer in a device to be manufactured. Before imprinting or embossing a stamp or an imprint roller in a layer of conductive paste, the conductive paste is provided on or over the substrate.

For example, the apparatus can include a deposition unit 544 for applying the conductive paste onto or over the substrate 101. Applying the conductive paste provides the layer 102 of conductive material. For example one or more deposition units 544 can coat the layer 102 using meniscus coating, slot die coating, doctor blade coating, gravure coating, flexographic coating or spray coating. After the layer 102 of the conductive paste has been deposited, a stamp, particularly an imprint roller as described herein, is used to emboss the pattern in the layer 102 to generate a patterned layer 104, as exemplary shown in FIG. 13.

More specifically, when the substrate 101 is moved through the gap between the imprint roller 200 and the other roller 502, a pattern of the stamp is embossed in the layer 102. This results in the patterned layer 104, as exemplarily illustrated in FIG. 13. The arrow 503 indicates a rotation of the other roller 502 around the axis 504 of the other roller 502. The arrow 121 in FIG. 13 indicates the movement of the substrate 101 through the gap between the imprint roller 200 and the other roller 502. The rollers rotate as indicated by the arrows 212 and 503. For example, according to some embodiments of the present disclosure, the substrate transport velocity along arrow 101 is similar to the cross-radial velocities, i.e. the tangential velocities, of the rollers.

According to some embodiments of the present disclosure, the apparatus 400 is configured for conducting a self-aligned imprint lithography (SAIL) process. For a SAIL process, i.e. a multi-level imprint lithography process, a recess in the stamp can have two or more feature depths of different portions of the feature. This can be very efficient for generating a pattern in a thin film. Accordingly, the master and consequently the template as described herein can be configured for providing a multilevel imprint structure. For instance, the stamp as described herein can be used for the manufacturing of lines such as connection lines with an imprint lithography process, e.g. a SAIL process, which allows for lines having a small width and small distances between the lines.

Further, as exemplarily shown in FIG. 13, the apparatus 400 may include a curing unit 532 for curing the imprinted layer, e.g. the conductive paste. The curing unit 532 can be selected from the group consisting of a light emission unit and a heating unit configured for curing the layer while imprinting the stamp in the layer, wherein emission 533 is generated. For example, the light emission unit can emit UV light, particularly in the wavelength range from 410 nm to 190 nm. In another example, the emission unit can emit IR light, particularly in the wavelength range from 9-11 micrometers (CO2 laser). In another example, the emission unit can emit broadband light from the IR to the UV with emission particularly in the wavelength range from 3 micrometers to 250 nm. This emission may be filtered to select only a portion of the blackbody emission using optical filters.

FIG. 13 shows an exemplary embodiment in which a curing unit 532 is configured to partially or fully cure the conductive paste while the stamp is imprinted into the layer of conductive paste. For instance, the degree of curing can be adjusted by the intensity of the curing unit, for example the light intensity or the heat emission intensity. Additionally or alternatively, the degree of curing can be adjusted by the rotational speed of the roller 502 and the substrate 101. The curing unit 532 can be positioned above the imprint roller 200, wherein the curing unit 532 can cure the layer while imprinting the stamp in the layer.

According to some embodiments, which can be combined with other embodiments described herein, the curing unit 532 can be configured to cure the layer through the stamp 200 by the emission 533. In particular, the curing unit 532 generates light 533, which penetrates the imprint roller 200 on the surface pointing away from the layer 102 and afterwards penetrates the imprint roller 200 on the surface facing the layer 102. The surface of the imprint roller 200, in particular the stamp 12 is penetrated twice by the light 533 when curing the layer 102 while imprinting the stamp in the layer. The curing process through the imprint roller 200 as described herein can be enabled and/or improved by a stabilization element according to embodiments described herein, in particular by a stabilization element which is permeable to radiation. According to some embodiments, the curing unit 533 can also be positioned within the roller 502. Furthermore, the processing apparatus 400 can also include two or more curing units 533.

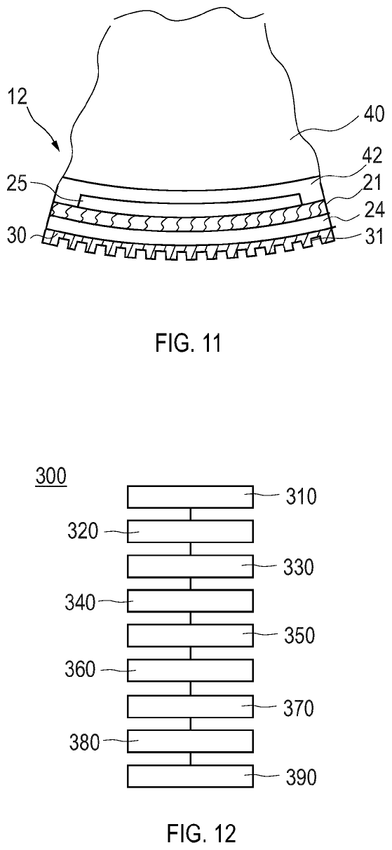

With reference to the flowchart shown in FIG. 12, a particular example of a method 300 of manufacturing a stamp for imprint lithography as shown, is described, which can be combined with other embodiments described herein. The method of manufacturing a stamp for imprint lithography includes coating a master with a first layer, the master provides a template of an imprint structure (block 310), curing the first layer (block 320), providing an intermediate layer over the first layer (block 330), and providing a second layer over the intermediate layer (block 340). The method further includes attaching a stabilization element to the second layer (block 350), curing the second layer by irradiating the second layer though the stabilization element (block 360), separating the master from the first layer to expose the imprint structure (block 370). The method further includes supporting the first layer by a support surface (block 380), providing an adhesion layer on exposed edge portions of the stabilization element, the second layer and the first layer, attaching the stabilization element to a stamp support structure, wherein attaching the stabilization element comprises rolling the stamp support structure over the stabilization element (block 390).

Accordingly, in view of the embodiments described herein, it is to be understood that compared to the state of the art improved methods of manufacturing a stamp for imprint lithography, improved stamps, improved imprint rollers and improved roll-to-roll substrate processing apparatus for imprint lithography are provided. In particular, embodiments as described herein overcome the problem that when manufacturing an imprint lithography stamp or an imprint roller, the dimensional stability can often not be maintained because the stamp is typically made of a soft material (e.g. PDMS). Additionally, embodiments as described herein address the problem that when manufacturing structures for displays, the structures need to line up with the pixels in the display, since a mismatch makes the imprint unusable. In other words, embodiments as described herein provide for substantially avoiding or even eliminating stamp imprint structure—pixel mismatch. Further, embodiments as described herein address the problem of dimensionally stabilizing the stamps, particularly the imprint structures, during transfer processes when creating an imprint roller.

Moreover, in view of the embodiments described herein it is to be understood that embodiments of the present disclosure beneficially provides a stabilization element wherein the soft stamp material cannot warp or distort any longer. Additionally, a distortion free handling and separation from the master becomes possible. Yet further, nanostructures will line up with the pixels in display. Furthermore, it is to be noted that the process can be applied to any imprint stamp production that uses precise conservation of the geometry of the master.

Additionally, embodiments of the present disclosure have the advantage that extremely good planarity of the back of the imprint structure can be provided, which can be useful for lamination of the stamp to an imprint roller. Further, it is to be noted that embodiments as described herein can be applied to any imprint process if geometry preservation of the imprint structure is crucial.

While the foregoing is directed to embodiments, other and further embodiments may be devised without departing from the basic scope, and the scope is determined by the claims that follow.

1. A method of manufacturing a stamp for imprint lithography, the method comprising:
coating a master with a layer system, comprising a first layer and a second layer, the second layer being on top of the first layer, the master providing a template of an imprint structure,
providing a stabilization element over the second layer, the stabilization element having a higher bending resistance than the second layer, and
separating the master from the layer system to expose the imprint structure.

2. The method of claim 1, further comprising curing the first layer.

3. The method of claim 1, further comprising curing the second layer.

4. The method of claim 1, further comprising attaching the stabilization element to the second layer.

5. The method of claim 1, wherein providing a stabilization element over the second layer further comprises providing an intermediate layer.

6. The method of claim 2, wherein curing the first layer comprises irradiating the first layer through the stabilization element.

7. The method of claim 3, wherein curing the second layer comprises irradiating the second layer through the stabilization element.

8. The method of claim 1, further comprising supporting the layer system by a support surface, the support surface being in contact with the imprint structure of the first layer.

9. The method of claim 1, further comprising providing an adhesion layer on exposed edge portions of the stabilization element, the second layer and the first layer.

10. The method of claim 1, further comprising attaching the stabilization element to a stamp support structure.

11. A stamp for imprint lithography, comprising:
a stamp support structure,
an imprint structure having a plurality of features generating a pattern upon imprinting the stamp in a layer, wherein the imprint structure is provided by a layer system comprising a first layer and a second layer, the second layer being on top of the first layer, and
a stabilization element over the second layer, the stabilization element being attached to the stamp support structure, the stabilization element having a higher bending resistance than the second layer.

12. The stamp according to claim 11, wherein the stabilization element is permeable to radiation.

13. The stamp of claim 11, the layer system further comprising an intermediate layer being arranged between the first layer and the second layer.

14. An imprint roller for a roll-to-roll substrate processing apparatus, the imprint roller comprising a stamp for imprint lithography, the stamp comprising:
a stamp support structure,
an imprint structure having a plurality of features generating a pattern upon imprinting the stamp in a layer, wherein the imprint structure is provided by a layer system comprising a first layer and a second layer, the second layer being on top of the first layer, and
a stabilization element over the second layer, the stabilization element being attached to the stamp support structure, the stabilization element having a higher bending resistance than the second layer, wherein the stamp support structure is a cylindrical support structure.

15. A roll-to-roll substrate processing apparatus, comprising an imprint roller for a roll-to-roll substrate processing apparatus, the imprint roller comprising a stamp for imprint lithography, the stamp comprising:
a stamp support structure,
an imprint structure having a plurality of features generating a pattern upon imprinting the stamp in a layer, wherein the imprint structure is provided by a layer system comprising a first layer and a second layer, the second layer being on top of the first layer, and
a stabilization element over the second layer, the stabilization element being attached to the stamp support structure, the stabilization element having a higher bending resistance than the second layer, wherein the stamp support structure is a cylindrical support structure.

16. The method of claim 1, wherein providing a stabilization element over the second layer further comprises attaching an intermediate layer to the second layer.

17. The method of claim 1, further comprising supporting the first layer by a support surface, the support surface being in contact with the imprint structure of the first layer.

18. The method of claim 10, wherein attaching the stabilization element comprises rolling the stamp support structure over the stabilization element.

19. The stamp according to claim 11, wherein the stabilization element is permeable to ultraviolet radiation.

20. A method of manufacturing a micro structured product, comprising using an imprint roller for a roll-to-roll substrate processing apparatus, the imprint roller comprising a stamp for imprint lithography, the stamp comprising:
a stamp support structure,
an imprint structure having a plurality of features generating a pattern upon imprinting the stamp in a layer, wherein the imprint structure is provided by a layer system comprising a first layer and a second layer, the second layer being on top of the first layer, and
a stabilization element over the second layer, the stabilization element being attached to the stamp support structure, the stabilization element having a higher bending resistance than the second layer, wherein the stamp support structure is a cylindrical support structure.
